(19) United States
(12) Patent Application Publication
(10) Pub. No.: US 2003/0010292 A1
(43) Pub. Date: Jan. 16, 2003

(54) Electrostatic chuck with dielectric coating

(75) Inventors: Arnold V. Kholodenko, San Francisco, CA (US); Michael G. Chafin, San Jose, CA (US); Brad Mays, San Jose, CA (US); Tetsuya Ishikawa, Santa Clara, CA (US); Ananda H. Kumar, Fremont, CA (US); Dennis S. Grimard, Ann Arbor, MI (US)

Correspondence Address: APPLIED MATERIALS, INC., 2881 SCOTT BLVD. M/S 2061, SANTA CLARA, CA, 95050, US

(73) Assignee: Applied Materials, Inc.

(21) Appl. No.: 09/907,328

(22) Filed: Jul. 16, 2001

(51) Int. Cl. C23F 1/00; C23C 16/00

(52) U.S. Cl. 118/728; 156/345.51

(57) ABSTRACT

Generally, an electrostatic chuck having a dielectric coating is provided. In one embodiment, an electrostatic chuck includes a support surface, a mounting surface disposed opposite the support surface and at least one side separating the support surface and the mounting surface which defines a support body. One or more conductive members are disposed within the support body to generate an electrostatic attraction between the body and a substrate disposed thereon. A dielectric coating is disposed on the mounting surface of the support body to minimize undesired current leakage therethrough. Optionally, the dielectric coating may be additionally disposed on one or more of the sides and/or the support surface.

### BACKGROUND OF THE DISCLOSURE

1. Field of the Invention

Embodiments of the invention generally relate to an electrostatic chuck for supporting a substrate within a substrate processing system.

2. Description of the Background Art

Substrate supports are widely used to support substrates within semiconductor wafer processing systems. A particular type of substrate support used in semiconductor wafer processing systems, such as a reactive ion etch (RIE) chamber or other processing systems, is an electrostatic chuck. Electrostatic chucks are used to retain substrates, such as semiconductor wafers or other workpieces, in a stationary position during processing. Typically, electrostatic chucks contain one or more electrodes embedded within a dielectric material such as ceramic. As power is applied to the electrode, an attractive force is generated between the electrostatic chuck and the substrate disposed thereon.

The attractive force is commonly generated through either a coulombic or a Johnsen-Rahbeck effect. Generally, electrostatic chucks utilizing coulombic attraction have electrodes disposed in bodies having high resistivities. The insulating properties of the body maintain a capacitive circuit (i.e., charge separation) between the electrodes and the substrate when an electrical potential is applied therebetween. Electrostatic chucks utilizing Johnsen-Rahbeck attraction have electrodes disposed in bodies having lower resistivities which allow charge migration through the body when power is applied to the electrodes. Charges (i.e., electrons) within the body migrate to portions of the surface of the electrostatic chuck making contact with the substrate when voltage is applied to the electrodes. Some minimal current passes between the chuck surface and the substrate at the contact point but generally not enough to result in device damage. Thus, as the charges accumulate at both sides of the contact points, a highly localized and powerful electric field is established between the substrate and electrostatic chuck. Since the attractive force is proportional to the distance between the opposite charges, the substrate is secured to the chuck with less power than necessary in chucks comprising high resistivity material (i.e., chucks having solely Coulombic attraction) as charge accumulates on the chuck's support surface close to the substrate. Examples of electrostatic chucks comprised of low resistivity material are described in U.S. Pat. No. 5,117,121 issued May 26, 1992 to Watanabe et al. and U.S. Pat. No. 5,463,526 issued Oct. 31, 1995 to Mundt, both of which are hereby incorporated by reference in their entireties.

As electrostatic chucks generally rely on the electric potential developed between the embedded electrodes and the substrate for the generation of attractive force, prevention of unintended and parasitic current leakage through the chuck body is paramount. For example, in a Johnsen-Rahbeck electrostatic chuck, plasma may contact the surface of the electrostatic chuck. As the plasma provides a current path between the electrostatic chuck and the chamber sidewalls that are normally grounded, the movement of charge through the body is diverted from the support surface to ground, substantially reducing the charge accumulation on the support surface resulting in diminished or lost attractive force. As the attractive force is decreased or lost, the substrate may move or become dislodged. A dislodged substrate is likely to become damaged or improperly processed. Current leakage from this or other reasons through the sides or bottom of the electrostatic chuck has a similar effect.

Therefore, a need exists for an improved electrostatic chuck.

### SUMMARY OF THE INVENTION

Generally, an electrostatic chuck having a dielectric coating is provided. In one embodiment, an electrostatic chuck includes a support surface, a mounting surface disposed opposite the support surface and at least one side separating the support surface and the mounting surface which define a support body. One or more conductive members are disposed within the support body. A dielectric coating is disposed on the mounting surface of the support body to minimize undesired current leakage therethrough. Optionally, the dielectric coating may be additionally disposed on one or more of the sides and/or support surface.

In another embodiment, an electrostatic chuck includes a ceramic support body having one or more conductive members disposed therein. The ceramic support body has a support surface adapted to support a substrate and an opposing mounting surface. A ceramic porous member is disposed within the body and is fluidly coupled to the support surface. A coating is disposed on the mounting surface of the support body.

In another aspect of the invention, a process chamber for processing a substrate is provided. In one embodiment, a process chamber for processing a substrate includes an evacuable chamber defining an interior volume and having a gas supply fluidly coupled thereto. A temperature control plate is disposed in the interior volume and supports an electrostatic chuck. The electrostatic chuck includes a support body having one or more conductive members disposed therein. The support body has an upper portion that includes a support surface. A lower portion of the support body has a mounting surface having a dielectric coating disposed thereon and is disposed on the temperature control plate.

### BRIEF DESCRIPTION OF THE DRAWINGS

So that the manner in which the above-recited features of the present invention are attained can be understood in detail, a more particular description of the invention, briefly summarized above, may be had by reference to the embodiments thereof which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a cross sectional schematic of a process chamber having one embodiment of a substrate support disposed therein;

FIG. 2 is a sectional view of the substrate support of FIG. 1; and

FIG. 3 depicts another embodiment of a substrate support;

To facilitate understanding, identical reference numerals have been used, wherever possible, to designate identical elements that are common to the figures.

### DETAILED DESCRIPTION

Generally, a process chamber having an electrostatic chuck disposed therein is provided. The electrostatic chuck generally includes a dielectric coating that minimizes current leakage from the electrostatic chuck, advantageously enhancing the attractive or chucking force. Although one embodiment of an electrostatic chuck is described illustratively in a Silicon Decoupled Plasma Source (DPS) CENTURA® etch system available from Applied Materials, Inc. of Santa Clara, Calif., the invention has utility in other process chambers including physical vapor deposition chambers, chemical vapor deposition chambers, other etch chambers and other applications where electrostatic chucking of a substrate is desired.

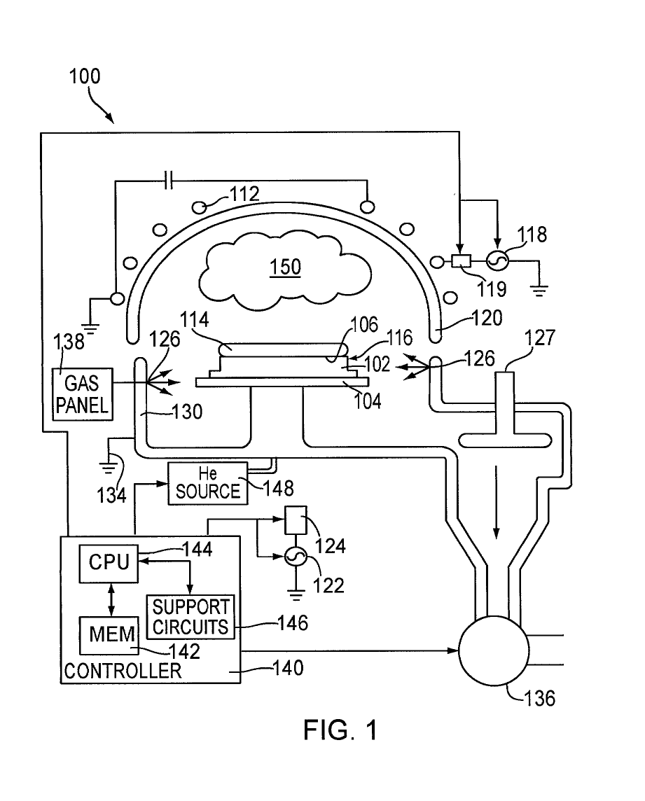

FIG. 1 depicts a schematic diagram of a DPS etch process chamber 100 that comprises at least one inductive coil antenna segment 112 positioned exterior to a dielectric, dome-shaped ceiling 120 (referred to hereinafter as the dome 120). An example of a process chamber that may be adapted to benefit from the invention is described in U.S. Pat. No. 5,583,737 issued Dec. 10, 1996 to Collins et al., which is hereby incorporated by reference in its entirety.

The antenna segment 112 is coupled to a radio-frequency (RF) source 118 that is generally capable of producing an RF signal. The RF source 118 is coupled to the antenna 112 through a matching network 119. Process chamber 100 also includes a substrate support pedestal 116 that is coupled to a second RF source 122 that is generally capable of producing an RF signal. The source 122 is coupled to the pedestal 116 through a matching network 124. The chamber 100 also contains a conductive chamber wall 130 that is connected to an electrical ground 134. A controller 140 comprising a central processing unit (CPU) 144, a memory 142, and support circuits 146 for the CPU 144 is coupled to the various components of the process chamber 100 to facilitate control of the etch process.

In operation, the semiconductor substrate 114 is placed on the substrate support pedestal 116 and gaseous components are supplied from a gas panel 138 to the process chamber 100 through entry ports 126 to form a gaseous mixture 150. The gaseous mixture 150 is ignited into a plasma in the process chamber 100 by applying RF power from the RF sources 118 and 122 respectively to the antenna 112 and the pedestal 116. The pressure within the interior of the etch chamber 100 is controlled using a throttle valve 127 situated between the chamber 100 and a vacuum pump 136. The temperature at the surface of the chamber walls 130 is controlled using liquid-containing conduits (not shown) that are located in the walls 130 of the chamber 100. Chemically reactive ions are released from the plasma and strike the substrate; thereby removing exposed material from the substrate's surface.

The pedestal 116 generally comprises an electrostatic chuck 102 disposed on a temperature control plate 104. The temperature of the substrate 114 is controlled by stabilizing the temperature of the electrostatic chuck 102 and flowing helium or other gas from a gas source 148 to a plenum defined between the substrate 114 and a support surface 106 of the electrostatic chuck 102. The helium gas is used to facilitate heat transfer between the substrate 114 and the pedestal 116. During the etch process, the substrate 114 is gradually heated by the plasma to a steady state temperature. Using thermal control of both the dome 120 and the pedestal 116, the substrate 114 is maintained at a predetermined temperature during processing.

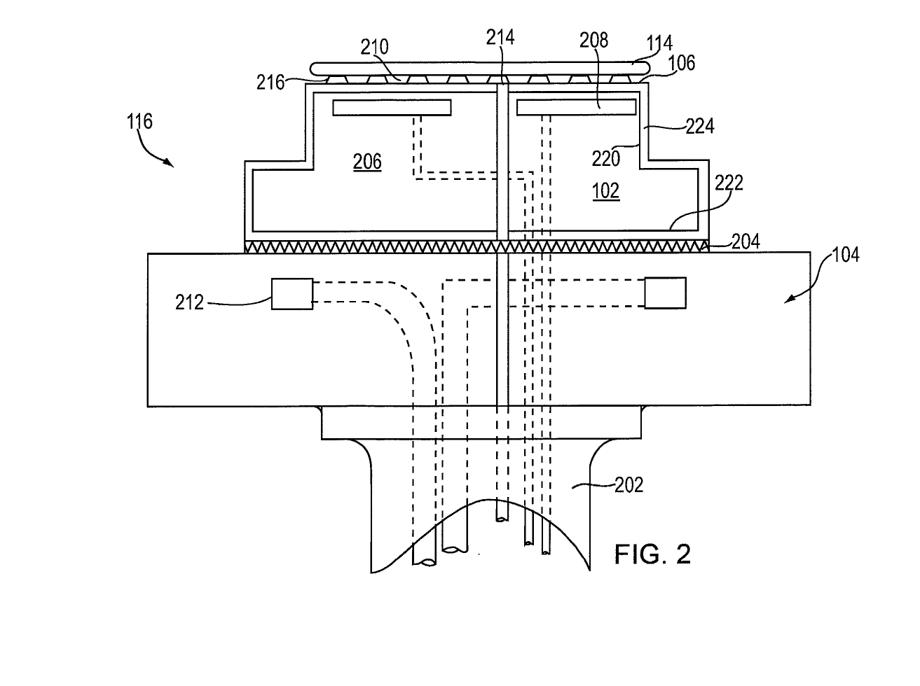

FIG. 2 depicts a vertical cross-sectional view of a first embodiment of the pedestal 116. The pedestal 116 is generally comprised of the temperature control plate 104 and the electrostatic chuck 102. The pedestal 116 is generally supported above the bottom of the chamber 100 by a shaft 202 coupled to the temperature control plate 104. The shaft 202 is typically welded, brazed or otherwise sealed to the temperature control plate 104 to isolate various conduits and electrical leads disposed therein from the process environment within the chamber 100.

The temperature control plate 104 is generally comprised of a metallic material such as stainless steel or aluminum. The temperature control plate 104 typically includes one or more passages 212 disposed therein that circulate a heat transfer fluid to maintain thermal control of the pedestal 116. Alternatively, the temperature control plate 104 may include an external coil, fluid jacket or thermoelectric device to provide temperature control.

The temperature control plate 104 may be screwed, clamped, adhered or otherwise fastened to the electrostatic chuck 102. In one embodiment, a heat transfer enhancing layer 204 is adhered between the temperature control plate 104 and the electrostatic chuck 102 thereby securing the plate 104 to the chuck 102. The heat transfer enhancing layer 204 is comprised of a number of thermally conductive materials and composites, including but not limited to conductive pastes, brazing alloys and adhesive coated, corrugated aluminum films.

The electrostatic chuck 102 is generally circular in form but may alternatively comprise other geometries to accommodate non-circular substrates, for example, square or rectangular flat panels. The electrostatic chuck 102 generally includes one or more electrodes 208 embedded within a support body 206. The electrodes 208 are typically comprised of an electrically conductive material such as copper, graphite and the like. Typical electrode structures include, but are not limited to, a pair of coplanar D-shaped electrodes, coplanar interdigital electrodes, a plurality of coaxial annular electrodes, a singular, circular electrode or other structure. The electrodes 208 are coupled to the RF source 118 by a feed through (not shown) disposed in the pedestal 116. One feed through that may be adapted to benefit from the invention is described in U.S. Pat. No. 5,730,803 issued Mar. 24, 1998, which is hereby incorporated by reference in its entirety.

The body 206 may comprise aluminum, ceramic, dielectric or a combination of one or more of the aforementioned materials. In one embodiment, the chuck body 206 is fabricated from a low resistivity ceramic material (i.e., a material having a resistivity between about 1xE⁹ to about 1×E¹¹ ohm-cm). Examples of low resistivity materials include doped ceramics such as alumina doped with titanium oxide or chromium oxide, doped aluminum oxide, doped boron-nitride and the like. Other materials of comparable resistivity, for example, aluminum nitride, may also be used. Such ceramic materials having relatively low resistivity generally promote a Johnsen-Rahbek attractive force between the substrate and electrostatic chuck 102 when power is applied to the electrodes 208. Alternatively, chuck body 206 comprising ceramic materials having resistivities equal to or greater than 1E×11 ohms-cm may also be used.

The electrostatic chuck 102 generally includes a dielectric coating 224 on at least one of the sides 220 or the bottom 222 of the chuck body 206. Generally, the dielectric coating 224 has a substantially higher resistivity (or lower dielectric constant) than the material comprising the chuck body 206. In one embodiment, the coating 224 is an electrically insulating material having a dielectric constant in the range of about 2.5 to about 7. Examples of such insulating materials include, but are not limited to, silicon nitride, silicon dioxide, aluminum dioxide, tantalum pentoxide, silicon carbide, polyimide and the like. The high surface or contact resistivity between the body 206 and the coating 224 substantial prevents electrons from passing therebetween. Moreover, the low dielectric constant of the coating 224 electrically insulates the chuck body 206 from the surrounding structure and environment (e.g., the temperature control plate 104, process gases, plasma and other conductive pathways) thus minimizing parasitic electrical losses that may reduce the electrical potential between the electrostatic chuck 102 and the substrate thereby resulting in reduction in the attractive forces.

In the preferred embodiment, the coating 224 is disposed on at least the bottom 222 of the chuck body 206. In another embodiment, the coating 224 is disposed on the side 220 of the chuck body 206. In yet another embodiment, the coating 224 is disposed on the support surface 106 of the chuck body 206. Alternatively, the coating 224 may be disposed on any combination of surfaces comprising the chuck body 206.

The coating 224 may be applied to the chuck body 206 using a variety of methods including adhesive film, spraying, encapsulation and other methods that coat one or more of the outer surfaces of the body 206. In one embodiment, the coating 224 is integrally fabricated to the body 206 by chemical vapor deposition, plasma spraying or by sputtering. Alternatively, when the coating 224 comprises a ceramic material, the coating 224 may be sintered or hot-pressed to the body 206 creating a single, monolithic ceramic member.

In one embodiment, the support surface 106 of the chuck body 206 may include a plurality of mesas 216 formed on the support surface 106. The mesas 216 are formed from one or more layers of an electrically insulating material having a dielectric constant in the range of about 2.5 to about 7. Examples of such insulating materials include, but are not limited to, silicon nitride, silicon dioxide, aluminum dioxide, tantalum pentoxide, silicon carbide, polyimide and the like. Alternatively, the mesas 216 may be formed from the same material as the chuck body and then coated with a high resistivity dielectric film.

In an embodiment of the chuck 102 utilizing the Johnson-Rahbeck effect, the ceramic chuck body 206 is partially conductive due to the relatively low resistivity of the ceramic thus allowing charges to migrate from the electrode 208 to the surface 106 of the chuck body 206. Similarly, charges migrate through the substrate 114 and accumulate on the substrate 114. The insulating material comprising or coating the mesas 216 prevents current flow therethrough. Since each of the mesas 216 has a significantly higher resistivity (i.e. lower dielectric constant) than the chuck body 206, the migrating charges accumulate proximate each of the mesas 216 on the surface 106 of the chuck 102. Although charges also migrate to the portions of the surface 106 between mesas 216, the dielectric constant of the mesa 216 is substantially greater than the dielectric constant of the backside gas within the plenum 210 between the backside of the substrate 114 and the chuck body surface which results in the electric field being substantially greater at each mesa than at locations outside of a mesa. Consequently, the clamping force is greatest at each mesa 216 and the invention enables the clamping force to be strictly controlled by placement of the mesas to achieve a uniform charge distribution across the backside of the substrate. One electrostatic chuck having mesas disposed on a support surface that may be adapted to benefit from the invention is described in U.S. Pat. No. 5,903,428 issued May 11, 1999 to Grimard et al., which is hereby incorporated by reference in its entirety.

To promote a uniform temperature across a substrate that is retained by the electrostatic chuck, a backside gas (e.g., helium or argon) is introduced to a plenum 210 defined between a support surface 106 of the electrostatic chuck 102 and the substrate 114 to provide a heat transfer medium therebetween. The backside gas is generally applied to the plenum through one or more outlets 214 formed through the chuck body 206.

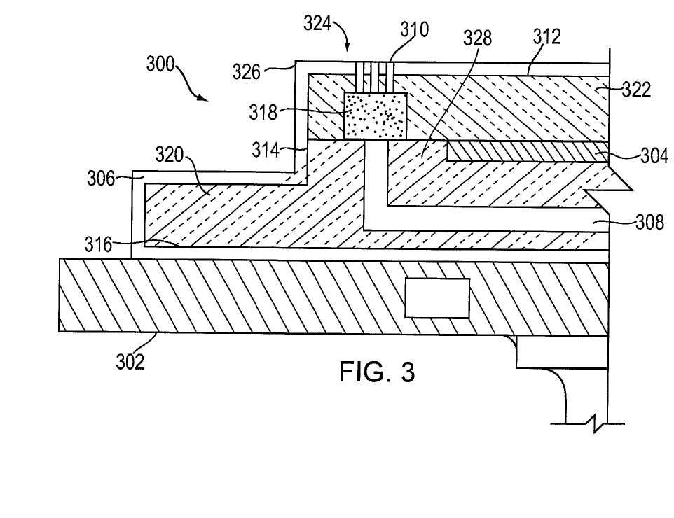

FIG. 3 depicts a partial sectional view of another embodiment of a pedestal 300. The pedestal 300 includes an electrostatic chuck 324 disposed on a temperature control plate 302. The pedestal 300 is generally configured similar to the pedestal 116 of FIGS. 1 and 2 except that the pedestal 300 includes a plurality of backside gas outlets 310 disposed proximate a perimeter 326 of a support surface 312 of the electrostatic chuck 324.

Generally, the electrostatic chuck 324 includes a body 328 having a bottom 316, sides 314 and the support surface 312. The body 328 may be comprised of materials similar to the body 206 described above. In one embodiment, the body 328 includes an upper portion 322 disposed on a lower portion 320. The lower portion 320 is coupled to a temperature control plate 302 and is generally comprised of a ceramic having a resistivity higher than a resistivity of the upper portion 322. One or more of the electrodes 304 are disposed between the upper and lower portions 322, 320 of the body 328. Alternatively, the electrodes 304 may be disposed on or in either the upper or lower portions 322, 320.

In the embodiment shown in FIG. 3, the upper portion 322 is disposed over the lower portion 320, thus encapsulating the electrodes 304. The upper portion 322 of the chuck body 328 is generally comprised of a low resistivity ceramic. As power is supplied to the electrodes 304, the low resistivity material comprising the upper portion 322 of the body 328 allows charge migration therethrough, thus establishing a Johnson-Rahbeck attraction force with a substrate disposed on the support surface 312. The higher resistivity material of the lower portion 320 substantially insulates the sides 314 and bottom 316 of the chuck body 328, thus minimizing the current leakage through those areas. To further protect the chuck 324 against parasitic current leakage, a coating 306 may be disposed on the bottom 316, sides 314 and support surface 312 or any combination thereof.

Backside gas is generally provided through the plurality of outlets 310 disposed on the support surface 312. The outlets 310 are generally coupled to a passage 308 disposed through the chuck body 328. A porous plug 318 is generally disposed between the outlets 310 and the passage 308. The porous plug 318 is generally comprised of a ceramic material such as aluminum oxide. The porous plug 318 is generally disposed in the upper portion 322 of the chuck body 328 while in the green state. The plug 318, the electrodes 304 and the upper and lower portions 322 of the body 328 are typically hot-pressed or sintered into a single monolithic ceramic member. Generally, the porous plug 318 prevents arcing and plasma ignition of the backside gas during processing and plasma cleaning by blocking a direct current path through the backside gas between the substrate and portions of the chuck in the passage 308 proximate the electrodes 304 while minimizing the surface area available for charge accumulation adjacent the backside gas flow path.

Although various embodiments which incorporate the teachings of the present invention have been shown and described in detail herein, those skilled in the art can readily devise many other varied embodiments that still incorporate these teachings.

What is claimed is:

1. A substrate support comprising:
a body having a support surface, a mounting surface disposed opposite the support surface and at least one side separating the support surface and mounting surface;
one or more conductive members disposed within the body; and
a dielectric coating disposed on at least the mounting surface.

2. The substrate support of claim 1, wherein the dielectric coating is additionally disposed on at least the support surface or the side.

3. The substrate support of claim 1, wherein the dielectric coating and support body are co-fired, hot pressed or sintered into a single member.

4. The substrate support of claim 1, wherein the dielectric coating comprises a material having a dielectric constant in the range of about 2.5 to about 7.

5. The substrate support of claim 1, wherein the dielectric coating comprises a material selected from the group consisting of silicon nitride, silicon dioxide, aluminum dioxide, tantalum pentoxide, silicon carbide and polyimide.

6. The substrate support of claim 1, wherein the body comprises a ceramic material.

7. The substrate support of claim 6, wherein the ceramic material has a resistivity between about 1E×9 to about 1E×11 ohms-cm.

8. The substrate support of claim 6, wherein the ceramic material has a resistivity equal to or greater than about 1E×11 ohms-cm.

9. The substrate support of claim 1 further comprising a porous member disposed within the body and fluidly coupled to the support surface.

10. The substrate support of claim 9, wherein the porous member comprises a ceramic material.

11. The substrate support of claim 9, wherein the porous member and support body are co-fired, hot pressed or sintered into a single member.

12. The substrate support of claim 9, wherein the body further comprises:
a portion separating the porous member from the support surface; and
one or more outlets disposed through the portion fluidly coupling the porous member to the support surface.

13. The substrate support of claim 1, wherein the body further comprises a plurality of mesas extending therefrom.

14. The substrate support of claim 13, wherein each mesa further comprises a dielectric layer disposed thereon.

15. A substrate support comprising:
a ceramic support body having a support surface adapted to support a substrate and an opposing mounting surface;
a plurality of holes disposed in the support surface coupled to a passage disposed in the body;
one or more conductive members disposed within the support body;
a coating disposed on at least the mounting surface; and
a ceramic porous member disposed within the passage and separated the support surface by a portion of the body having the holes disposed therein.

16. The substrate support of claim 15, wherein the dielectric coating is additionally disposed on at least the support surface or a side of the body.

17. The substrate support of claim 15, wherein the dielectric coating comprises a material having a dielectric constant in the range of about 2.5 to about 7.

18. The substrate support of claim 15, wherein the dielectric coating comprises a material selected from the group consisting of silicon nitride, silicon dioxide, aluminum dioxide, tantalum pentoxide, silicon carbide and polyimide.

19. The substrate support of claim 15, wherein the ceramic support body further comprises:
an upper portion having a resistivity between about 1E×9 to about 1E×11 ohms-cm disposed between the conductive member and the support surface; and
a lower portion.

20. The substrate support of claim 19, wherein the lower portion of the ceramic support body has a resistivity higher than the resistivity of the upper portion.

21. The substrate support of claim 19, wherein the porous member, the upper portion of the body and the lower portion of the body are co-fired, sintered or hot pressed into a single member.

22. The substrate support of claim 15, wherein the porous member, the coating, the upper portion of the body and the lower portion of the body are co-fired, sintered or hot pressed into a single member.

23. A process chamber for processing a substrate comprising:
an evacuable chamber defining an interior volume;
a gas supply fluidly coupled to the interior volume;
a temperature control plate disposed in the interior volume; and
an electrostatic chuck comprising:
a support body having an upper portion and a lower portion, the upper portion having a support surface and the lower portion having a mounting surface disposed on the temperature control plate;
one or more conductive members disposed in the support body; and
a dielectric coating disposed on the mounting surface.

24. The process chamber of claim 23, wherein the electrostatic chuck further comprises:
at least one passage disposed in the lower portion of the support body and having a first end at least partially closed by the upper portion;
at least one outlet disposed through the upper portion of the support body and fluidly coupling the passage to the support surface; and
a porous member disposed within the passage.

25. The process chamber of claim 24, wherein the support body and porous member are comprised of ceramic and are co-fired, sintered or hot pressed into a single member.

26. The process chamber of claim 24, wherein the evacuable chamber is an etch chamber, physical deposition chamber or a chemical vapor deposition chamber.

27. The process chamber of claim 24, wherein the dielectric coating is additionally disposed on at least the support surface or a side of the body.
